(19) United States
(12) Patent Application Publication
(10) Pub. No.: US 2013/0341723 A1
(43) Pub. Date: Dec. 26, 2013

(54) MEMORY CELL WITH ASYMMETRIC READ PORT TRANSISTORS

(71) Applicants: Niladri N. Mojumder, Fishkill, NY (US); Randy W. Mann, Milton, NY (US); Anurag Mittal, Wappingers Falls, NY (US)

(72) Inventors: Niladri N. Mojumder, Fishkill, NY (US); Randy W. Mann, Milton, NY (US); Anurag Mittal, Wappingers Falls, NY (US)

(73) Assignee: GLOBALFOUNDRIES INC., Grand Cayman (KY)

(21) Appl. No.: 13/531,969

(22) Filed: Jun. 25, 2012

(51) Int. Cl. H01L 27/088; H01L 21/336

(52) U.S. Cl. 257/368; 438/289; 257/E27.06; 257/E21.409

(57) ABSTRACT

A memory cell includes a storage element and a read port. The read port includes a first transistor having a first gate coupled to the storage element, a first source region, and a first drain region. The second transistor includes a second gate, a second source region coupled to the first drain region, and a second drain region. A first dopant profile of the first and second source regions is asymmetric with respect to a second dopant profile of the first and second drain regions.

### CROSS-REFERENCE TO RELATED APPLICATIONS

Not applicable.

### BACKGROUND

The disclosed subject matter relates generally to semiconductor devices and, more particularly, to a memory cell with asymmetric read port transistors.

Semiconductor memory devices are in widespread use in many modern integrated circuit devices and in many consumer products. In general, memory devices are the means by which electrical information is stored. There are many types of memory devices, SRAMs (Static Random Access Memory), DRAMs (Dynamic Random Access Memory), ROMs (Read Only Memory), etc., each of which has its own advantages and disadvantages relative to other types of memory devices. For example, SRAMs are typically employed in applications where higher speed and/or reduced power consumption is important, e.g., cache memory of a microprocessor, mobile phones and other mobile consumer products, etc. Millions of such memory devices are typically included in even very basic electronic consumer products.

Irrespective of the type of memory device, there is a constant drive in the industry to increase the performance and durability of such memory devices. In typical operations, an electrical charge (HIGH) is stored in the memory device to represent a digital “1”, while the absence of such an electrical charge or a relatively low charge (LOW) stored in the device indicates a digital “0”. Special read/write circuitry is used to access the memory device to store digital information on such a memory device and to determine whether or not a charge is presently stored in the memory device. These program/erase cycles (“P/E cycles”) typically occur millions of times for a single memory device over its effective lifetime.

In general, efforts have been made to reduce the physical size of such memory devices, particularly reducing the physical size of components of the memory devices, such as transistors, to increase the density of memory devices, thereby increasing performance and decreasing the costs of the integrated circuits incorporating such memory devices. Increases in the density of the memory devices may be accomplished by forming smaller structures within the memory device and by reducing the separation between the memory devices and/or between the structures that make up the memory device. Often, these smaller design rules are accompanied by layout, design and architectural modifications which are either made possible by the reduced sizes of the memory device or its components, or such modifications are necessary to maintain performance when such smaller design rules are implemented. As an example, the reduced operating voltages used in many modern-day conventional integrated circuits are made possible by improvements in design, such as reduced gate insulation thicknesses in the component transistors and improved tolerance controls in lithographic processing. On the other hand, reduced design rules make reduced operating voltages essential to limit the effects of hot carriers generated in small size devices operating at higher, previously conventional operating voltages.

Making SRAMs in accordance with smaller design rules, as well as using reduced internal operating voltages, can reduce the stability of SRAM cells. Reduced operating voltages and other design changes can reduce the voltage margins which ensure that an SRAM cell remains in a stable data state during a data read operation, increasing the likelihood that the read operation could render indeterminate or lose entirely the data stored in the SRAM cell.

In SRAM cells, the read margin is a performance parameter that limits the size of the achievable cells. The pass transistor must allow the memory cell to be read without reducing the charge at the storage node far enough to turn off the pull-down transistor. The sizes and/or doping characteristics of the pass and pull-down transistors are controlled to provide an adequate read margin. To reduce the constraints associated with maintaining the read margin, a conventional SRAM cell may be modified to include a read port that allows the cell to be read without disturbing the charge on the storage node. A read port includes two additional NMOS transistors. Although the read port allows the SRAM cell to be read without disturbing the storage nodes, the additional transistors result in additional active and standby leakage power consumption as compared to a conventional SRAM cell.

This section of this document is intended to introduce various aspects of art that may be related to various aspects of the disclosed subject matter described and/or claimed below. This section provides background information to facilitate a better understanding of the various aspects of the disclosed subject matter. It should be understood that the statements in this section of this document are to be read in this light, and not as admissions of prior art. The disclosed subject matter is directed to overcoming, or at least reducing the effects of, one or more of the problems set forth above.

### BRIEF SUMMARY

The following presents a simplified summary of the disclosed subject matter in order to provide a basic understanding of some aspects of the disclosed subject matter. This summary is not an exhaustive overview of the disclosed subject matter. It is not intended to identify key or critical elements of the disclosed subject matter or to delineate the scope of the disclosed subject matter. Its sole purpose is to present some concepts in a simplified form as a prelude to the more detailed description that is discussed later.

One aspect of the disclosed subject matter is seen in a memory cell including a storage element and a read port. The read port includes a first transistor having a first gate coupled to the storage element, a first source region, and a first drain region. The second transistor includes a second gate, a second source region coupled to the first drain region, and a second drain region. A first dopant profile of the first and second source regions is asymmetric with respect to a second dopant profile of the first and second drain regions.

Another aspect of the disclosed subject matter is seen in a method for forming a memory cell. A storage element of the memory cell is formed. A read port of the memory cell is defined by forming a first transistor having a first gate coupled to the storage element, a first source region, and a first drain region; and forming a second transistor having a second gate, a second source region coupled to the first drain region, and a second drain region. Forming the first and second transistors includes forming a first dopant profile in the first and second source regions, and forming a second dopant profile in the first and second drain regions that is asymmetric with respect to the first dopant profile.

### BRIEF DESCRIPTION OF THE SEVERAL VIEWS OF THE DRAWINGS

The disclosed subject matter will hereafter be described with reference to the accompanying drawings, wherein like reference numerals denote like elements, and:

FIG. 1 is a diagram of a memory cell with an asymmetric read port in accordance with one aspect of the present subject matter;

FIG. 2 is an exemplary cross-section device diagram of a pull-down transistor and a pass gate transistor in the asymmetric read port of FIG. 1;

FIG. 3 is a diagram of the read port of FIG. 2 in an earlier manufacturing stage to illustrate a method for forming the asymmetric extension regions;

FIG. 4 is a diagram of the read port of FIG. 1 in an earlier manufacturing stage to illustrate a method for forming the asymmetric characteristics of the pull-down transistor and the pass gate transistor by varying the halo dopant profile;

FIG. 5 is a diagram of the read port of FIG. 2 in an earlier manufacturing stage where the asymmetric halo doping also includes using different maximum implant angles in lieu of or in combination with different dopant concentrations for the source halo region and the drain halo region;

FIG. 6 is a diagram of the read port of FIG. 2 showing both asymmetric extension regions and different strength and positioned halo regions;

FIG. 7 is a top view of the read port illustrating the relative gate lengths of the pull-down transistor and the pass gate transistor.

While the disclosed subject matter is susceptible to various modifications and alternative forms, specific embodiments thereof have been shown by way of example in the drawings and are herein described in detail. It should be understood, however, that the description herein of specific embodiments is not intended to limit the disclosed subject matter to the particular forms disclosed, but on the contrary, the intention is to cover all modifications, equivalents, and alternatives falling within the spirit and scope of the disclosed subject matter as defined by the appended claims.

### DETAILED DESCRIPTION

One or more specific embodiments of the disclosed subject matter will be described below. It is specifically intended that the disclosed subject matter not be limited to the embodiments and illustrations contained herein, but include modified forms of those embodiments including portions of the embodiments and combinations of elements of different embodiments as come within the scope of the following claims. It should be appreciated that in the development of any such actual implementation, as in any engineering or design project, numerous implementation-specific decisions must be made to achieve the developers' specific goals, such as compliance with system-related and business related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure. Nothing in this application is considered critical or essential to the disclosed subject matter unless explicitly indicated as being “critical” or “essential.”

The disclosed subject matter will now be described with reference to the attached figures. Various structures, systems and devices are schematically depicted in the drawings for purposes of explanation only and so as to not obscure the disclosed subject matter with details that are well known to those skilled in the art. Nevertheless, the attached drawings are included to describe and explain illustrative examples of the disclosed subject matter. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

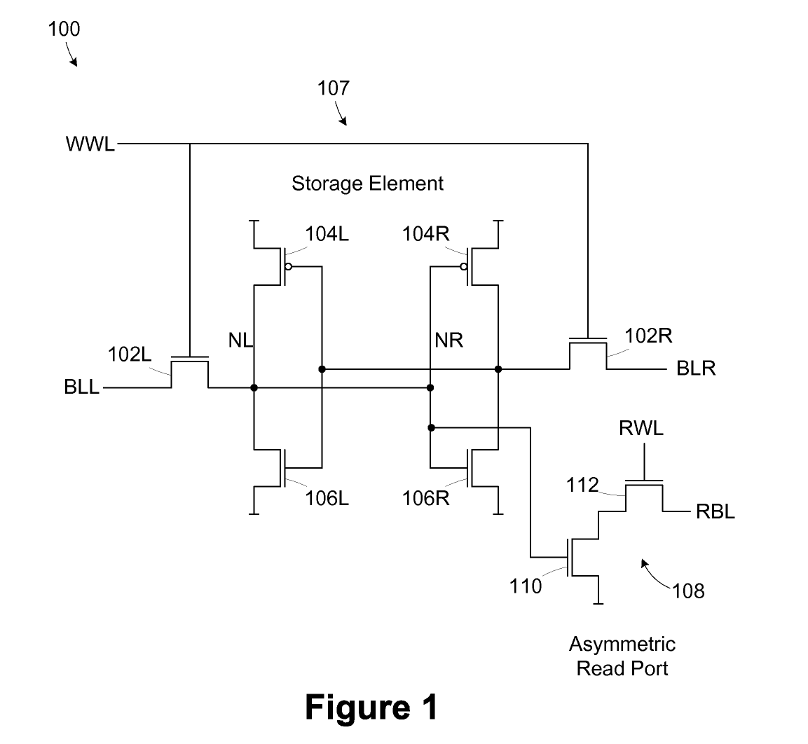

Referring now to the drawings wherein like reference numbers correspond to similar components throughout the several views and, specifically, referring to FIG. 1, the disclosed subject matter shall be described in the context of an SRAM memory cell 100 includes two NMOS pass gate transistors 102L/R (left/right), two PMOS pull-up transistors 104L/R, and two NMOS pull-down transistors 106L/R. The transistors 102,104, 106 may be collectively referred to as a storage element 107 of the SRAM cell 100. Data is read out of the storage element 107 of the SRAM cell 100 in a non-destructive manner using a asymmetric read port 108 including an NMOS pull-down transistor 110 and an NMOS pass gate transistor 112. As will be described in greater detail below, the read port 108 is asymmetric in that the doping of the NMOS pull-down transistor 110 and the NMOS pass gate transistor 112 are asymmetric with respect to the source and drain dopant profiles. Although the various transistors in the SRAM cell 100 are illustrated as being N or P type devices, it is contemplated that complementary devices may be used and logic signals may be inverted accordingly to achieve the same logical results.

Each of the PMOS pull-up transistors 104L/R has its gate connected to the gate of a corresponding NMOS pull-down transistor 106L/R. The drains of the PMOS pull-up transistors 104L/R have their drains connected to the drains of corresponding NMOS pull-down transistors 106L/R to form inverters having the conventional configuration. The sources of the PMOS pull-up transistors 104L/R are connected to a high reference potential, typically VCC, and the sources of the NMOS pull-down transistors 106L/R are connected to a lower reference potential, typically VSS or ground. The gates of the PMOS pull-up transistor 104L and the NMOS pull-down transistor 106L, which make up one inverter, are connected to the drains of the transistors 104R, 106R of the other inverter. Similarly, the gates of the PMOS pull-up transistor 104R and the NMOS pull-down transistor 106R, which make up the other inverter, are connected to the drains of the transistors 104L, 106L. Hence, the potential present on the drains of the transistors 104L, 106L (node NL) of the first inverter is applied to the gates of transistors 104R, 106R of the second inverter and the charge serves to keep the second inverter in an ON or OFF state. The logically opposite potential is present on the drains of the transistors 104R, 106R (node NR) of the second inverter and on the gates of the transistors 104L, 106L of the first inverter, keeping the first inverter in the complementary OFF or ON state relative to the second inverter.

Thus, the latch of the illustrated SRAM cell 100 has two stable states: a first state with a predefined potential present on charge storage node NL and a low potential on charge storage node NR (logic “1”); and a second state with a low potential on charge storage node NL and the predefined potential on charge storage node NR (logic “0”). Binary data are stored in the SRAM cell 100 by toggling between the two states of the latch. Sufficient charge must be stored on the charge storage nodes NL, NR, and thus on the coupled gates of associated inverters, to unambiguously hold one of the inverters “ON” and unambiguously hold the other of the inverters “OFF”, thereby preserving the memory state. The stability of an SRAM cell 100 can be quantified by the margin by which the potential on the charge storage nodes can vary from its nominal value while still keeping the SRAM cell 100 in its original state.

Data is read out of the SRAM cell 100 using the asymmetric read port 108. If a logic “1” is present at the node NR (corresponding to a logic “0” data value being present in the SRAM cell 100), the NMOS pull-down transistor 110 is enabled, grounding its drain. In contrast, if a logic “1” is present at the node NR, the NMOS pull-down transistor 110 is not enabled, thereby allowing its drain to float. When a signal is asserted on the read word line (RWL), the read bit line (RBL) is coupled to the drain of the NMOS pull-down transistor 110, resulting in the voltage on the RBL dropping if a logic “0” was stored in the SRAM cell 100 and floating if a logic “1” was stored in the SRAM cell 100. Sense logic (not shown) is operable to detect the voltage drop or lack thereof to determine the data value stored in the SRAM cell 100. Reading the SRAM cell 100 through the read port 108 does not significantly disturb the voltages stored on the nodes NL and NR, as compared to the reading of a conventional 6T SRAM cell.

Write access to the SRAM cell 100 is provided through a write word line (WWL) and left and right bit lines (BLL, BLR). Complimentary logic signals are asserted on the left and right bit lines, and the write word line (WWL) is asserted to write the values into the SRAM cell 100.

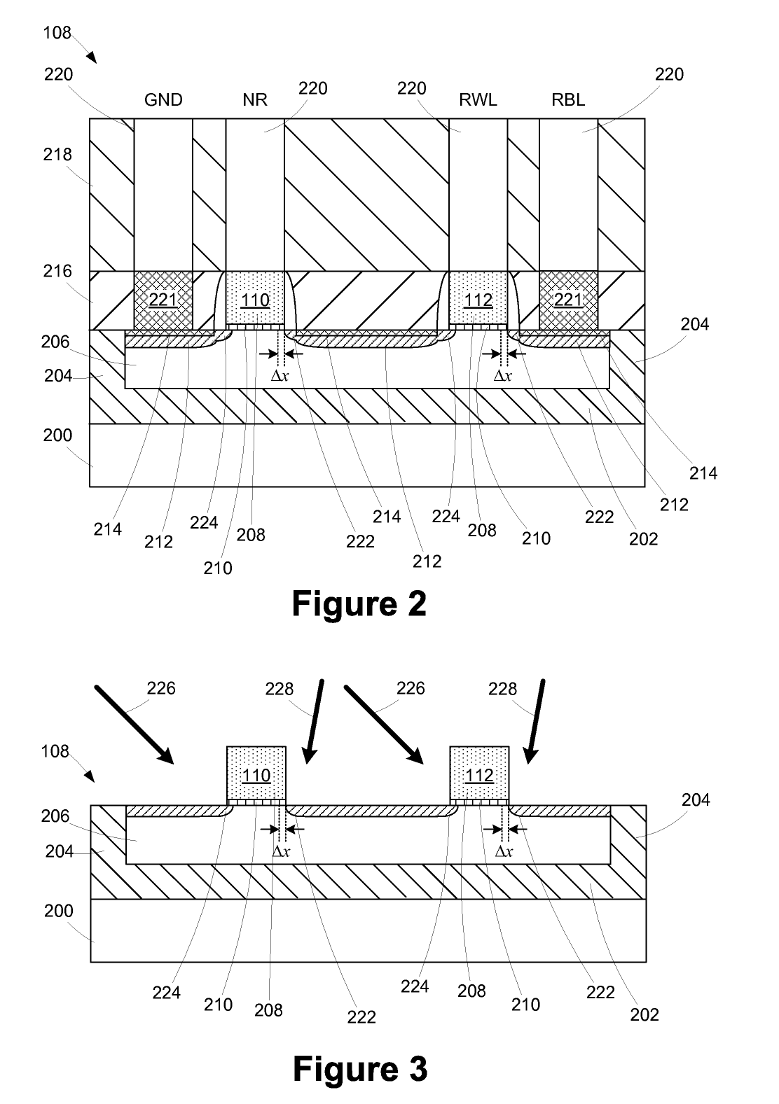

FIG. 2 illustrates an exemplary cross-section device diagram of the pull-down transistor 110 and the pass gate transistor 112 of the asymmetric read port 108. Typically, the pull-down transistor 110 and the pass gate transistor 112 are NMOS transistor devices. The general functions performed by these transistors in a typical SRAM memory device are well known to those skilled in the art. The pull-down transistor 110 and the pass gate transistor 112 are formed in and above a semiconducting substrate 200. The pull-down transistor 110 and the pass gate transistor 112 are bounded by a buried insulation layer 202 and isolation structures 204 (e.g., a shallow trench isolation structure) formed in the substrate 200. In the illustrative embodiment, the semiconducting substrate 200 is a silicon-on-insulator (SOI) substrate comprised of bulk silicon 200, a buried insulation layer 202 (commonly referred to as a “BOX” layer), and an active region 206 (in and above which semiconductor devices are formed), which may also be a silicon material. Of course, the present invention may also be employed when the substrate 200 is made of semiconducting materials other than silicon and/or it may be in another form, such as a bulk silicon configuration. Thus, the terms substrate or semiconductor substrate should be understood to cover all forms of semiconductor structures.

At the stage of manufacture depicted in FIG. 2, illustrative and schematically depicted generic transistor structures formed for each of the pull-down transistor 110 and the pass gate transistor 112. The illustrative transistor structures include an illustrative gate electrode 208 and a gate insulation layer 210. The active region 206 is P-doped, and N-doped source and drain regions 212 are defined in the active region 206. The source and drain region 212 defined between the pull-down transistor 110 and the pass gate transistor 112 is shared, thereby forming the interconnection between the drain of the pull-down transistor 110 and the source of the pass gate transistor 112 illustrated in FIG. 1. Silicide regions 214 may be defined in the source and drain regions 212. A stressed dielectric layer 216 (e.g., tensile stressed silicon nitride) is formed above the active region 206, an interlayer dielectric layer 218 (e.g., silicon dioxide or a low-k dielectric) is formed above the layer 216, and interconnect structures 220 are formed through the dielectric layers 216, 218 to contact the gate electrodes 208 and the silicide regions 214. The interconnect structures 220 may include trench silicide regions 221. Of course, the materials of construction for the illustrative transistor structures may, and likely will, vary depending upon the particular application. Thus, the presently disclosed subject matter should not be considered as limited to any particular type of transistor structure, the composition and materials of construction for such structures, or the manner in which such structures are made. For example, the transistor structures may be made using techniques well known to those skilled in the art, such as gate-last or gate-first techniques, although the drawings depict an illustrative gate-first technique.

As indicated above, the read port 108 is asymmetric in that the doping of the NMOS pull-down transistor 110 and the NMOS pass gate transistor 112 are asymmetric with respect to the source and drain dopant profiles. In FIG. 2, the pull-down transistor 110 and the pass gate transistor 112 have drain extension regions 222 that are offset with respect to the source extension regions 224 by Δx nm. Reducing or eliminating the gate-to-drain extension overlap compared to the gate-to-source extension overlap reduces the drain capacitance, gate-to-drain leakage, and drain induced barrier lowering (DIBL) of pull-down transistor 110 and the pass gate transistor 112. The relatively larger gate-to-source extension overlap helps in maintaining or even bossing the device ON current during a read operation.

FIG. 3 is a diagram of the read port 108 of FIG. 2 in an earlier manufacturing stage to illustrate a method for forming the asymmetric extension regions 222, 224. The extension regions 222, 224 are typically formed using angled dopant implants (e.g., of N type dopant ions), where the implant varies between a vertical implant angle and an oblique implant angle. As illustrated in FIG. 3, the maximum oblique implant angle 226 for the source side portion of the implant is greater than the maximum oblique implant angle 228 for the drain side portion of the implant. The gate electrode 208 serves to shadow the drain during the source implant, so the dopants are introduced further beneath the gate electrode 208 on the source side. The different maximum angles result in different amounts of dopant being introduced beneath the gate electrodes 208, thereby resulting in the asymmetric dopant profile. In one embodiment, only a vertical implant may be used on the drain size, resulting in minimal gate-to-drain extension region overlap. Some overlap may be present due to dopant diffusion during subsequent heat treatments.

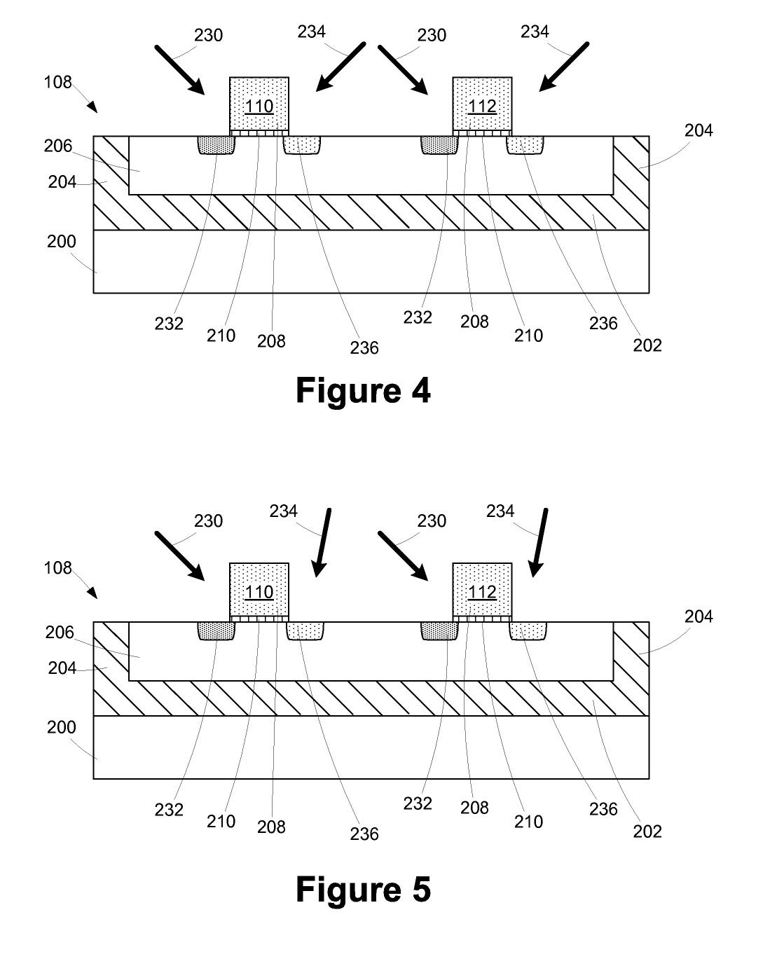

FIG. 4 is a diagram of the read port 108 of FIG. 2 in an earlier manufacturing stage to illustrate a method for forming the asymmetric characteristics of the pull-down transistor 110 and the pass gate transistor 112 by varying the halo dopant profile. A halo implant is generally performed to counterdope the source and drain regions to provide a sharper dopant transition at the PN junction between the P-doped active region 206 and the N-doped source and drain regions 212 and their associated extension regions 222, 224. As illustrated in FIG. 4, a source side halo implant 230 is used to from a source halo region 232, and drain side halo implant 234 is used to from a drain halo region 236. In the illustrated embodiment, the implant angles are the same for the halo implants 230, 234, but the dopant concentration is different so that the source halo region 232 is stronger than the drain halo region 236. In one embodiment, the drain side halo implant 234 may be completely omitted, so the dopant profile asymmetry arises from the presence of the source halo region 232 and the absence of the drain halo region 236.

FIG. 5 is a diagram of the read port 108 of FIG. 2 in an earlier manufacturing stage where the asymmetric halo doping also includes using different maximum implant angles in lieu of or in combination with different dopant concentrations for the source halo region 232 and the drain halo region 236. Similar to the result for the source and drain extension regions 222, 224 formed in FIG. 3, the use of different maximum implant angles generates a gate to source halo overlap that is different than the gate to drain halo overlap.

The asymmetric halo regions 232, 236 illustrated in FIGS. 4 and 5 enable asymmetric electric field magnitudes. The presence of the stronger source halo region 232 results in a higher electric field and higher carrier injection velocity. These effects result in higher device ON current both in the linear and saturation regions of transistor operation. However, the weaker or absent halo regions 236 on the drain side improves the DIBL, thereby reducing the junction leakage and capacitance.

The intrinsic device delay for the transistors 110, 112 can be approximated as, T=CV/I_{ON}, where C is the total drain capacitance of the device, V is the read voltage and I_{ON} is the drive current. If the magnitude of rate of decrease in C goes past beyond the magnitude of I_{ON} decrease due to asymmetric gate edge shift, the read speed for the SRAM cell 100 improves.

The various asymmetric doping techniques described herein may be used in isolation or combined. Although the asymmetric dopant profiles are illustrated as being formed using different implant angles and/or dopant concentrations, it is contemplated that selective masking techniques may also be used in conjunction with dopant implants to generate asymmetric dopant profiles.

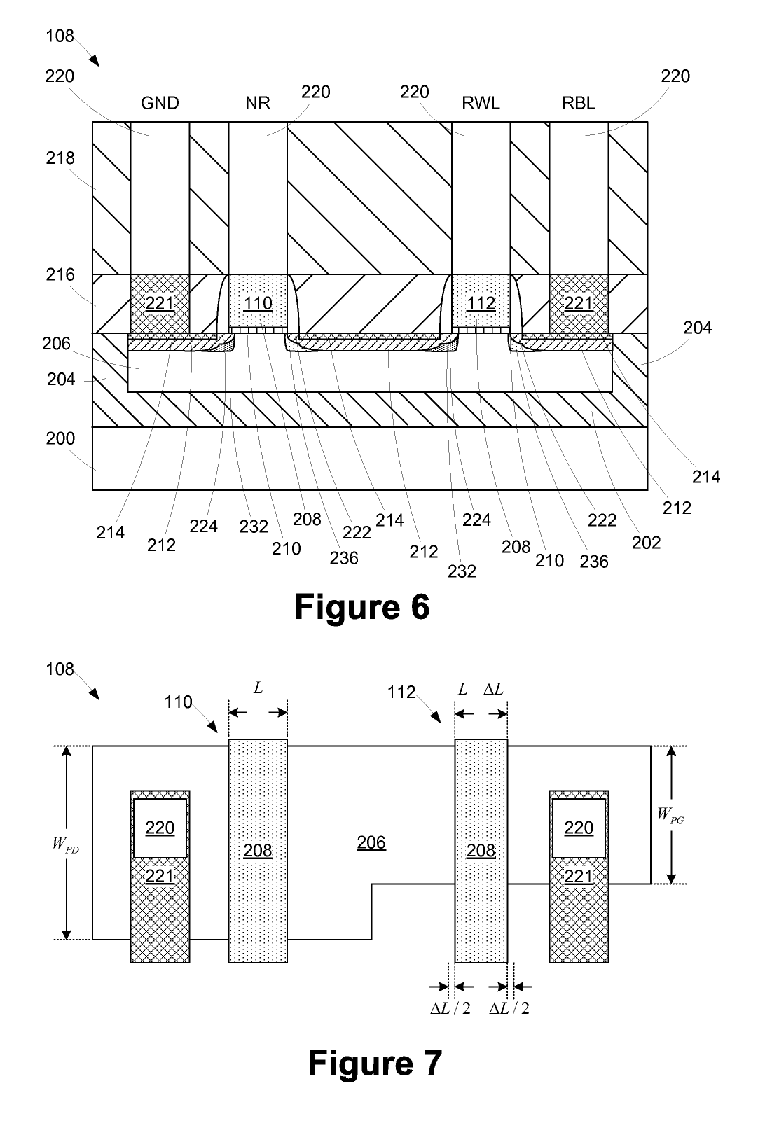

FIG. 6 is a diagram of the read port 108 of FIG. 2 showing both asymmetric extension regions 222, 224 and different strength and positioned halo regions 232, 236. Combining the asymmetric doping techniques enables additional tuning of the device parameters.

FIG. 7 is a top view of the read port illustrating the relative gate lengths of the pull-down transistor 110 and the pass gate transistor 112. The width of the pull-down transistor 110, W_{PD}, is greater than the width of the pass gate transistor 112, W_{PG} to provide different relative current capacities. To compensate for the increases in capacitance due to the asymmetric doping techniques described herein, the gate length of the pass gate transistor 112 (L−ΔL) may be reduced with respect to that of the pull-down transistor 110 (L). Reducing the gate length by ΔL increases the spacing between the gate electrode 208 of the pass gate transistor 112 and the trench silicide region 221 by a factor of ΔL/2. This length difference reduces the gate to trench silicide coupling capacitance (fringing capacitance) and also the gate to channel capacitance for the pass gate transistor 112. This length compensation reduces the active power consumed by the RBL during read operations and also improves the read frequency of the SRAM cell 100.

The different types of dopant asymmetry described herein may be applied together or independently to achieve better short channel effects and higher device performance, leading to lower active and standby leakage current and higher read frequency. The various embodiments for the asymmetric read port 108 described herein allow optimization of the pull-down transistor 110 and pass gate transistor 112 more precisely in terms of critical parameters, such as linear threshold voltage (VTₗᵢₙ), saturation threshold voltage (VTₛₐₜ), standby leakage, junction capacitance, etc.).

The particular embodiments disclosed above are illustrative only, as the disclosed subject matter may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the disclosed subject matter. Accordingly, the protection sought herein is as set forth in the claims below.

We claim:

1. A memory cell, comprising:
a storage element;
a read port, comprising:
a first transistor having a first gate coupled to the storage element, a first source region, and a first drain region; and
a second transistor having a second gate, a second source region coupled to the first drain region, and a second drain region,
wherein a first dopant profile of the first and second source regions is asymmetric with respect to a second dopant profile of the first and second drain regions.

2. The memory cell of claim 1, wherein the first and second source regions include first and second source extension regions, respectively, the first and second drain regions include first and second drain extension regions, respectively, and a first overlap between the first and second source extension regions and the respective first and second gates is greater than a second overlap between the first and second drain extension regions and the respective first and second gates.

3. The memory cell of claim 2, wherein the first and second source regions include first and second source halo regions, respectively, the first and second drain regions include first and second drain halo regions, respectively, and a first overlap between the first and second source halo regions and the respective first and second gates is greater than a second overlap between the first and second drain halo regions and the respective first and second gates.

4. The memory cell of claim 3, wherein a first dopant concentration of the first and second source halo regions is greater than a second dopant concentration of the first and second drain halo regions.

5. The memory cell of claim 2, wherein the first and second source regions include first and second source halo regions, respectively, the first and second drain regions include first and second drain halo regions, respectively, and a first dopant concentration of the first and second source halo regions is greater than a second dopant concentration of the first and second drain halo regions.

6. The memory cell of claim 2, wherein the first and second source regions include first and second source halo regions, respectively, and the first and second drain regions do not include halo regions.

7. The memory cell of claim 1, wherein the first and second source regions include first and second source halo regions, respectively, the first and second drain regions include first and second drain halo regions, respectively, and a first overlap between the first and second source halo regions and the respective first and second gates is greater than a second overlap between the first and second drain halo regions and the respective first and second gates.

8. The memory cell of claim 7, wherein a first dopant concentration of the first and second source halo regions is greater than a second dopant concentration of the first and second drain halo regions.

9. The memory cell of claim 1, wherein the first and second source regions include first and second source halo regions, respectively, the first and second drain regions include first and second drain halo regions, respectively, and a first dopant concentration of the first and second source halo regions is greater than a second dopant concentration of the first and second drain halo regions.

10. The memory cell of claim 1, wherein the first and second source regions include first and second source halo regions, respectively, and the first and second drain regions do not include halo regions.

11. The memory cell of claim 1, wherein the first gate has a first gate length and the second gate has a second gate length less than the first gate length.

12. The memory cell of claim 1, wherein the storage element and the read port define a static random access memory cell.

13. A method for forming a memory cell, comprising:
forming a storage element of the memory cell;
forming a read port of the memory cell by forming a first transistor having a first gate coupled to the storage element, a first source region, and a first drain region; and forming a second transistor having a second gate, a second source region coupled to the first drain region, and a second drain region,
wherein forming the first and second transistors comprises forming a first dopant profile in the first and second source regions, and forming a second dopant profile in the first and second drain regions that is asymmetric with respect to the first dopant profile.

14. The method of claim 13, wherein the first and second source regions include first and second source extension regions, respectively, the first and second drain regions include first and second drain extension regions, respectively, forming the first dopant profile comprises forming the first and second source extension regions to define a first overlap between the first and second source extension regions and the respective first and second gates, and forming the second dopant profile comprises forming the first and second drain extension regions to define a second overlap between the first and second drain extension regions and the respective first and second gates that is less than the first overlap.

15. The method of claim 14, wherein the first and second source regions include first and second source halo regions, respectively, the first and second drain regions include first and second drain halo regions, respectively, forming the first dopant profile comprises forming the first and second source halo regions to define a first overlap between the first and second source halo regions and the respective first and second gates, and forming the second dopant profile comprises forming the first and second drain halo regions to define a second overlap between the first and second source halo regions and the respective first and second gates that is less than the first overlap.

16. The method of claim 15, wherein forming the first dopant profile comprises forming the first and second source halo regions having a first dopant concentration, and forming the second dopant concentration comprises forming the first and second drain halo regions having a second dopant concentration less than the first dopant concentration.

17. The method of claim 14, wherein the first and second source regions include first and second source halo regions, respectively, the first and second drain regions include first and second drain halo regions, respectively, forming the first dopant profile comprises forming the first and second source halo regions having a first dopant concentration, and forming the second dopant profile comprises forming the first and second drain halo regions having a second dopant concentration less than the first dopant concentration.

18. The method of claim 14, wherein the first and second source regions include first and second source halo regions, respectively, and the first and second drain regions do not include halo regions.

19. The method of claim 13, wherein the first and second source regions include first and second source halo regions, respectively, the first and second drain regions include first and second drain halo regions, respectively, forming the first dopant profile comprises forming the first and second source halo regions to define a first overlap between the first and second source halo regions and the respective first and second gates, and forming the second dopant profile comprises forming the first and second drain halo regions to define a second overlap between the first and second source halo regions and the respective first and second gates that is less than the first overlap.

20. The method of claim 19, wherein forming the first dopant profile comprises forming the first and second source halo regions having a first dopant concentration, and forming the second dopant concentration comprises forming the first and second drain halo regions having a second dopant concentration less than the first dopant concentration.

21. The method of claim 13, wherein the first and second source regions include first and second source halo regions, respectively, the first and second drain regions include first and second drain halo regions, respectively, forming the first dopant profile comprises forming the first and second source halo regions having a first dopant concentration, and forming the second dopant profile comprises forming the first and second drain halo regions having a second dopant concentration less than the first dopant concentration.

22. The method of claim 13, wherein forming the first dopant profile comprises forming first and second source halo regions in the first and second source regions, respectively, and forming the second dopant profile comprises forming the first and second drain regions without halo regions.

23. The method of claim 13, wherein forming the first transistor comprises forming the first gate having a first gate length and forming the second transistor comprises forming the second gate having a second gate length less than the first gate length.
